(19) United States
(12) Patent Application Publication
(10) Pub. No.: US 2024/0006519 A1
(43) Pub. Date: Jan. 4, 2024

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Yosuke SAKURAI, Azumino-city (JP); Seiji NOGUCHI, Matsumoto-city (JP); Daisuke OZAKI, Okaya-city (JP); Ryutaro HAMASAKI, Matsumoto-city (JP); Takuya YAMADA, Matsumoto-city (JP); Yoshihiro IKURA, Matsumoto-city (JP)

(21) Appl. No.: 18/469,541

(22) Filed: Sep. 18, 2023

Related U.S. Application Data
(63) Continuation of application No. PCT/JP2022/038348, filed on Oct. 14, 2022.

(30) Foreign Application Priority Data
Oct. 15, 2021 (JP) 2021-169472

(51) Int. Cl. H01L 29/739; H01L 29/66; H01L 29/10

(52) U.S. Cl. CPC H01L 29/7397; H01L 29/66734; H01L 29/1095

(57) ABSTRACT

Provided is a semiconductor device comprising: a semiconductor substrate including a drift region of a first conductivity type; a base region of a second conductivity type provided between the drift region and the upper surface of the semiconductor substrate; a plurality of trench portions provided from the upper surface of the semiconductor substrate to below the base region; a lower end region of the second conductivity type provided in contact with lower ends of two or more trench portions; a well region of the second conductivity type which is provided from the upper surface of the semiconductor substrate to below the base region, and has a higher doping concentration than the base region; and a high resistance region of the second conductivity type which is arranged between the lower end region and the well region in the top view and has a lower doping concentration than the lower end region.

The contents of the following patent application(s) are incorporated herein by reference:
NO. 2021-169472 filed in JP on Oct. 15, 2021
NO. PCT/JP2022/038348 filed in WO on Oct. 14, 2022

### BACKGROUND

### 1. Technical Field

The present invention relates to a semiconductor device and a method for manufacturing the semiconductor device.

### 2. Related Art

A structure has been hitherto known in which a floating region of a P type away from a well region of the P type is provided at a bottom portion of a gate trench (see Patent Document 1, for example).

### PRIOR ART DOCUMENT

### Patent Document

Patent Document 1: Japanese Patent Application Publication No. 2019-91892

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates a view showing an example of a cross section e-e in FIG. 2.

FIG. 4 illustrates a view showing an example of arrangement of a well region 11 and a lower end region 202 in a top view.

FIG. 5A illustrates a view showing an example of a cross section f-f in FIG. 4.

FIG. 5B illustrates a view showing an example of net doping concentration distribution in a cross section a-a and a cross section b-b in FIG. 5A.

FIG. 6 illustrates a view showing an example of doping concentration distribution in an X axis direction.

FIG. 7 illustrates a view showing an example of a cross section g-g in FIG. 4.

FIG. 8 shows a result obtained by measuring relationship between a doping concentration of a high resistance region 204 and breakdown voltage of a portion where the high resistance region 204 is formed.

FIG. 9 illustrates a view showing another example of arrangement of the high resistance region 204 in a top view.

FIG. 10 illustrates a view showing another example of arrangement of the high resistance region 204 in a top view.

FIG. 11 illustrates a view showing part of a process of a method for manufacturing the semiconductor device 100.

FIG. 12 illustrates a view describing an example of a second region forming step S1104.

FIG. 13 illustrates a view describing another example of the second region forming step S1104.

FIG. 14 illustrates a view describing another example of the second region forming step S1104.

FIG. 15 illustrates a view showing another example of doping concentration distribution in an X axis direction.

FIG. 16 illustrates a view showing another example of doping concentration distribution in an X axis direction.

FIG. 17 illustrates a view showing another example of doping concentration distribution in an X axis direction.

FIG. 18 illustrates a view showing another example of doping concentration distribution in an X axis direction.

FIG. 19 illustrates a view showing another example of configuration of the lower end region 202 and the high resistance region 204.

FIG. 20 illustrates a view showing an example of doping concentration distribution of the high resistance region 204.

FIG. 21 illustrates a view showing another example of arrangement of the high resistance region 204 in an X axis direction.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

Further, a region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N D and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but the invention is not limited to these. The bulk donor of this example is phosphorous. The bulk donor is also contained in a P type region. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. Further, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type. In the specification, a unit system is the SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by voltage-capacitance profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

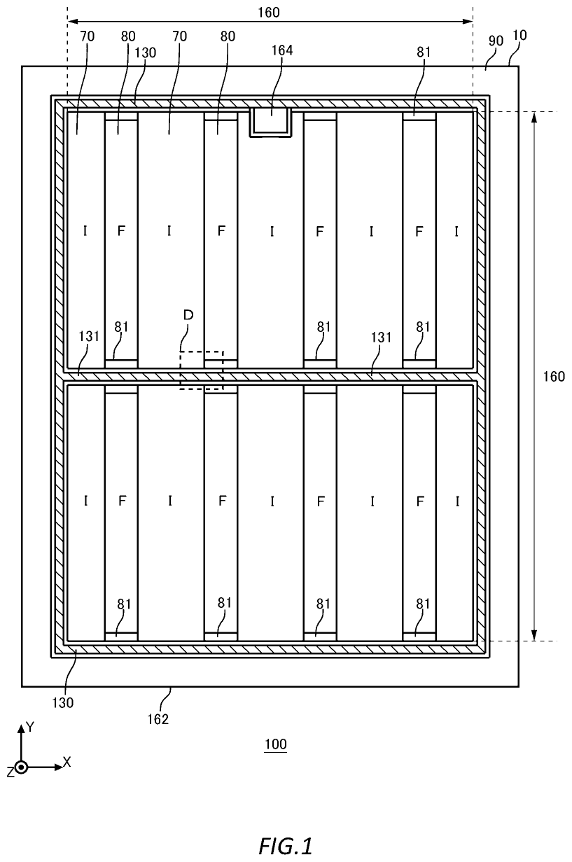

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 facing each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region overlapping the emitter electrode in the top view. In addition, a region sandwiched between the active portions 160 in the top view may also be included in the active portion 160.

The active portion 160 is provided with a transistor portion 70 including a transistor element such as an IGBT (Insulated Gate Bipolar Transistor). The active portion 160 may further be provided with a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol F. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of P+ type may be provided in a region other than the cathode region. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is a P type region having a higher concentration than the base region described below, and is formed from the upper surface of the semiconductor substrate 10 to a position deeper than the base region. A region enclosed by the well region in the top view may be the active portion 160.

The outer circumferential gate runner 130 is connected to the gate pad 164. The outer circumferential gate runner 130 is arranged above the semiconductor substrate 10. The outer circumferential gate runner 130 may be a metal wire including aluminum or the like.

The active-side gate runner 131 is provided in the active portion 160. Providing the active-side gate runner 131 in the active portion 160 can reduce variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 substantially at the center of the Y axis direction, the outer circumferential gate runner 130 enclosing the active portion 160. When the active portion 160 is divided by the active-side gate runner 131, the transistor portion 70 and the diode portion 80 may be alternately arranged in the X axis direction in each divided region.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

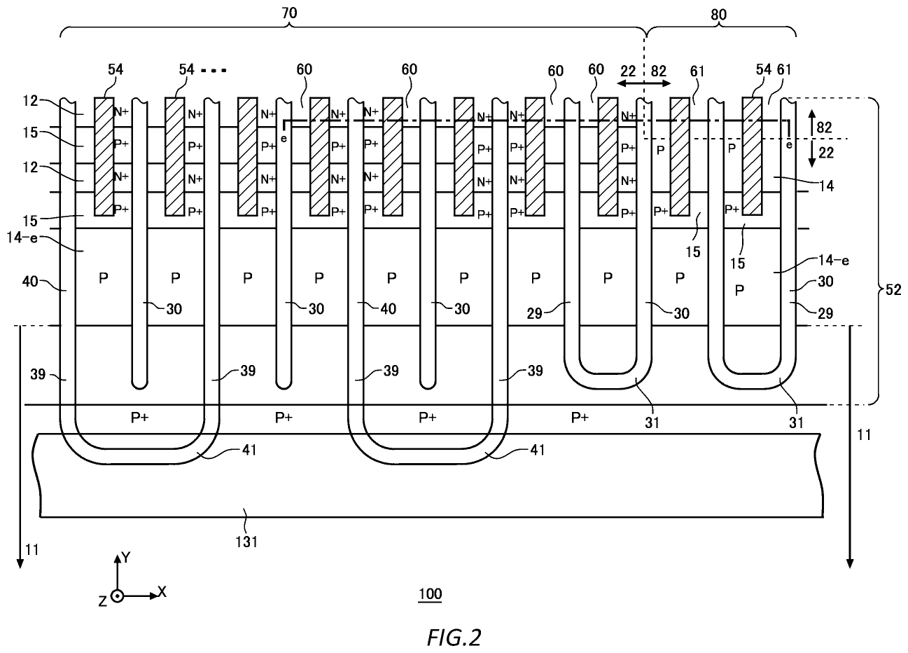

FIG. 2 illustrates an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region in which the doping concentration is higher than the base region 14. The base region 14 of this example is a P− type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom portion in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at the other end portion of each mesa portion. Each mesa portion may be provided with at least one of a first conductivity type of emitter region 12, and a second conductivity type of contact region 15 in a region sandwiched between the base regions 14-e in the top view. The emitter region 12 of this example is an N+ type, and the contact region is a P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of an n+ type is provided in a region in direct contact with the lower surface of the semiconductor substrate 10. On the lower surface of the semiconductor substrate 10, a collector region of the p+ type 22 may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged separately from the well region 11 in the y axis direction. With this configuration, the distance between the p type region (the well region 11) having a relatively high doping concentration and formed up to the deep position, and the cathode region 82 is ensured, so that the breakdown voltage can be improved. The end portion in the y axis direction of the cathode region 82 of this example is arranged farther away from the well region 11 than the end portion in the y axis direction of the contact hole 54. In another example, the end portion in the y axis direction of the cathode region 82 may be arranged between the well region 11 and the contact hole 54.

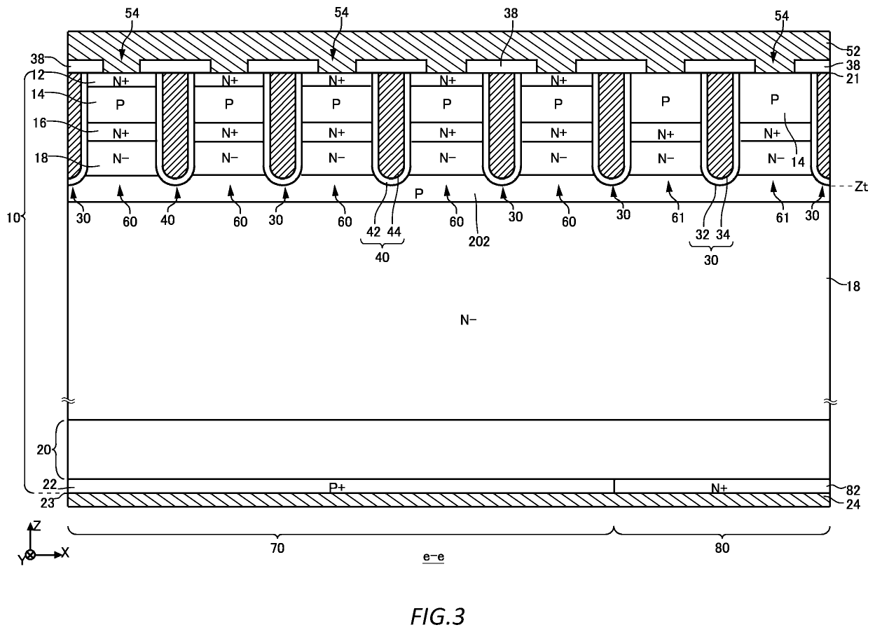

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with the contact hole 54 described in FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the specification, the direction in which the emitter electrode 52 is connected to the collector electrode 24 (the z axis direction) is referred to as a depth direction.

The semiconductor substrate 10 includes a drift region 18 of an N type or N− type. The drift region 18 is provided in each of the transistor portion 70 and the diode portion 80.

In the mesa portion 60 of the transistor portion 70, an emitter region 12 of an N+ type and the base region 14 of the P− type are provided in order from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed on the upper surface 21 of the semiconductor substrate and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is a region of the N+ type with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the P− type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. The doping concentration of the buffer region 20 is higher than the doping concentration of the drift region 18. The buffer region 20 may have a concentration peak having a higher doping concentration than the drift region 18. The doping concentration of the concentration peak refers to a doping concentration at a local maximum of the concentration peak. Further, as the doping concentration of the drift region 18, an average doping concentration in the region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a chemical concentration peak of hydrogen (proton) or phosphorous. The buffer region 20 may function as a field stopper layer which prevents a depletion layer expanding from the lower end of the base region 14 from reaching the collector region of the P+ type 22 and the cathode region 82 of the N+ type 82.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the above described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided to below the base region 14. In a region where at least any one of the emitter region 12, the contact region 15, or the accumulation region 16 is provided, each trench portion also passes through the doping regions described above. The configuration of the trench portion passing through the doping region is not limited to the one manufactured in the order of forming the doping region and then forming the trench portion. The configuration of the trench portion passing through the doping region includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as those of the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon or the like. The dummy conductive portion 34 may have the same length as that of the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottom portions of the dummy trench portion 30 and the gate trench portion 40 may be formed in a curved-surface shape (a curved-line shape in the cross section) convexly downward. In the present specification, a depth position of the lower end of the gate trench portion 40 is defined as Zt.

The semiconductor device 100 of this example includes a lower end region 202 of a P type provided in contact with a lower end of the trench portion. A doping concentration of the lower end region 202 may be equal to or lower than a doping concentration of the base region 14. The doping concentration of the lower end region 202 of this example is lower than the doping concentration of the base region 14.

The lower end region 202 is arranged away from the base region 14. A region of an N type (at least one of the accumulation region 16 or the drift region 18, in this example) is provided between the lower end region 202 and the base region 14.

The lower end region 202 is continuously provided to be in contact with lower ends of two or more trench portions in the X axis direction. That is, the lower end region 202 is provided to cover a mesa portion between the trench portions. The lower end region 202 may cover a plurality of mesa portions.

The lower end region 202 may be in contact with the lower ends of the two or more trench portions in each transistor portion 70. In addition, the lower end region 202 may be in contact with lower ends of two or more gate trench portions 40 in each transistor portion 70. The lower end region 202 may be in contact with lower ends of all trench portions in at least one transistor portion 70. In addition, the lower end region 202 may be in contact with lower ends of all gate trench portions 40 in at least one transistor portion 70.

The lower end region 202 may be in contact with the lower ends of the two or more trench portions in each diode portion 80. The lower end region 202 may be in contact with the lower ends of all trench portions in at least one diode portion 80.

The lower end region 202 is provided to extend in a Y axis direction. A length of the lower end region 202 in the Y axis direction is shorter than a length of the trench portion in the Y axis direction. In addition, the length of the lower end region 202 in the Y axis direction may be equal to or larger than 50%, may be equal to or larger than 70%, or may be equal to or larger than 90% of the length of the trench portion in the Y axis direction.

Providing the lower end region 202 can suppress potential rise in the vicinity of the lower end of the trench portion when the semiconductor device 100 is turned on. Thus, it is possible to reduce a slope (dv/dt) of a waveform of emitter-collector voltage at the time of turn-on and to reduce noise in a voltage or current waveform at the time of switching.

Note that potential of the lower end region 202 is different from potential of the emitter electrode 52. As mentioned above, the lower end region 202 is arranged away from the base region 14 connected to the emitter electrode 52 in the Z axis direction. In addition, the lower end region 202 is arranged away from the well region connected to the emitter electrode 52 in a top view. The active portion 160 may have a portion where the lower end region 202 is not provided in at least one of the X axis direction or the Y axis direction.

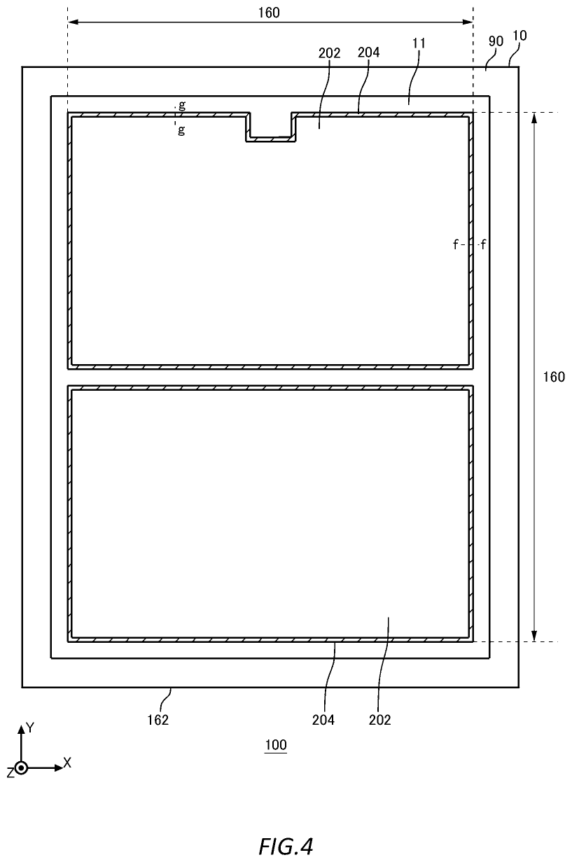

FIG. 4 illustrates a view showing an example of arrangement of the well region 11 and the lower end region 202 in a top view. The lower end region 202 of this example is provided in the active portion 160. The lower end region 202 may be provided in a region occupying 50% or more, may be provided in a region occupying 70% or more, or may be provided in a region occupying 90% or more of the active portion 160 in the top view.

The well region 11 is provided below the gate runner shown in the FIG. 1. The well region 11 and the lower end region 202 are arranged at different positions in the top view. As shown in FIG. 4, the well region 11 may be arranged to enclose the lower end region 202 in the top view. As shown in FIG. 4, if the lower end region 202 is divided into a plurality of regions, the well region 11 may enclose each lower end region 202.

The well region 11 and the lower end region 202 are arranged away from each other in the top view. The semiconductor device 100 includes a high resistance region 204 arranged between the well region 11 and the lower end region 202 in the top view. The high resistance region 204 may be arranged at a position in contact with the well region 11 in the active portion 160. In FIG. 4, the high resistance region 204 is hatched with diagonal lines. The high resistance region 204 may enclose the lower end region 202 in the top view. The high resistance region 204 may enclose the active portion 160 in the top view.

The high resistance region 204 is a region of a P− type having a lower doping concentration than the lower end region 202. That is, the high resistance region 204 is a region having higher electrical resistance than the lower end region 202. The high resistance region 204 may connect the lower end region 202 and the well region 11. Providing the lower end region 202 can reduce noise at the time of switching. Then, providing the high resistance region 204 can reduce difference in breakdown voltage between a region which is provided with the lower end region 202 and a region which is not provided with the lower end region 202 and can improve withstand capability of the semiconductor device 100. In addition, providing the high resistance region 204 between the well region 11 and the lower end region 202 can prevent the lower end region 202 and the well region 11 from having the same potential. This can suppress the lower end region 202 from having emitter potential and operate the transistor portion 70 and the diode portion 80.

In this example, the high resistance region 204 is provided all over the region where the lower end region 202 is not provided in the active portion 160. Note that, if there is a portion where the lower end region 202 is not provided inside the active portion 160, the high resistance region 204 may also be provided in the portion. The high resistance region 204 arranged inside the active portion 160 may be enclosed by the lower end region 202 in the top view.

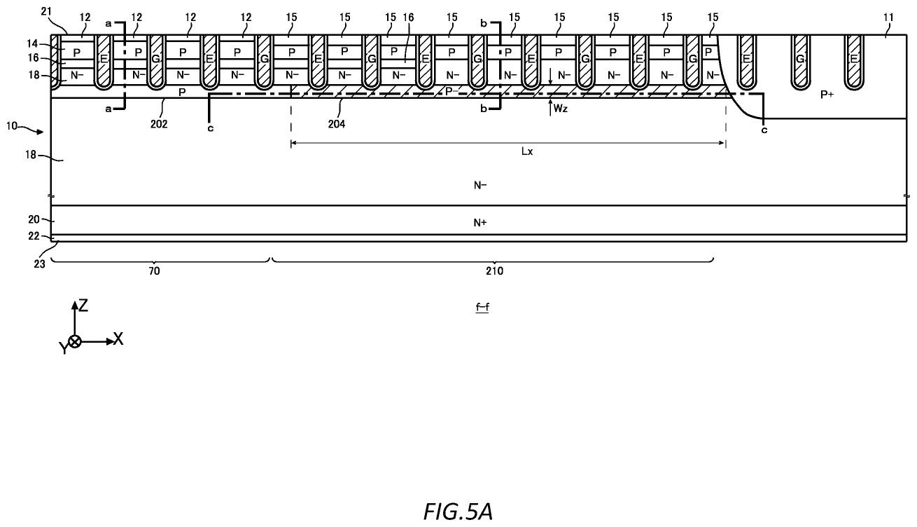

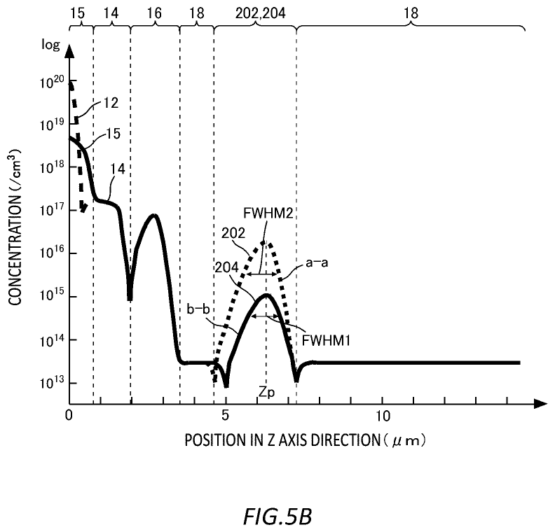

FIG. 5A illustrates a view showing an example of a cross section f-f in FIG. 4. The cross section f-f is an XZ plane passing through the lower end region 202, the high resistance region 204, and the well region 11. That is, the cross section f-f is the XZ plane in the vicinity of a boundary between the active portion 160 and the well region 11. Note that FIG. 5A shows a structure of the semiconductor substrate 10 and omits components such as an electrode and a dielectric film arranged above and below the semiconductor substrate 10. In addition, in FIG. 5A, the gate trench portion 40 is indicated by a sign G and the dummy trench portion 30 is indicated by a sign E.

The cross section f-f shown in FIG. 5A includes the transistor portion 70 which is arranged at an end in an X axis direction among a plurality of transistor portions 70. A structure of the transistor portion 70 is similar to that of the transistor portion 70 described in FIG. 2 and FIG. 3. Note that, in FIG. 5A, one dummy trench portion 30 is arrayed between two gate trench portions 40 like G/E/G/E/ . . . , but two dummy trench portions 30 may be arrayed between the two gate trench portions 40 like G/E/E/G/E/E/ . . .

An array of the gate trench portions 40 and the dummy trench portions 30 may have another structure. A region between the transistor portion 70 and the well region 11 shown in FIG. 5A is defined as a boundary portion 210. A center of the gate trench portion 40 (G) arranged at the end in the X axis direction among the gate trench portions 40 (G) provided in direct contact with the emitter regions 12 is defined as an end portion of the transistor portion 70 in the X axis direction. A range of the boundary portion 210 in the X axis direction is defined to be from the gate trench portion 40 (G) to the well region 11.

The well region 11 is provided from the upper surface 21 of the semiconductor substrate 10 to below the base region 14. The well region 11 is a region of a P+ type having a higher doping concentration than the base region 14.

One or more trench portions are provided in the boundary portion 210. The one or more gate trench portions 40 and the one or more dummy trench portions 30 are provided in the boundary portion 210 of this example. An array of the trench portions in the X axis direction in the boundary portion 210 may be the same as or may be different from the one in the transistor portion 70.

The base region 14 is provided in a mesa portion of the boundary portion 210. The contact region 15 may be provided between the base region 14 and the upper surface 21 of the semiconductor substrate 10. In addition, the accumulation regions 16 may be provided in one or more mesa portions closest to the transistor portion 70 among mesa portions of the boundary portion 210.

The lower end region 202 of this example is a region of a P type having a lower doping concentration than the well region 11. The lower end region 202 is arranged in at least part of a region of the transistor portion 70. The lower end region 202 of this example extends closer to the well region 11 than an end portion of the transistor portion 70. In another example, the lower end region 202 may be terminated at the end portion of the transistor portion 70 or may be terminated inside the transistor portion 70.

The high resistance region 204 is a region of a P− type having a lower doping concentration than the lower end region 202. The high resistance region 204 is provided in at least part of the boundary portion 210 in the X axis direction. The high resistance region 204 may be provided all over the boundary portion 210 in the X axis direction. The high resistance region 204 may be in contact with the lower end region 202 and may be in contact with the well region 11. The high resistance region 204 of this example is in contact with both the lower end region 202 and the well region 11.

The high resistance region 204 and the emitter region 12 may be arranged away from each other in a top view. That is, the high resistance region 204 may not be provided in the transistor portion 70. Distance between the high resistance region 204 and the emitter region 12 in the top view may be equal to or larger than a width of the mesa portion in the X axis direction.

Part of the high resistance region 204 and part of the accumulation region 16 may be arranged to overlap each other in the top view. The accumulation region 16 may also be provided in the boundary portion 210.

The high resistance region 204 may have a portion provided at the same depth position as that of the lower end region 202. That is, a range in a Z axis direction where the high resistance region 204 is provided and a range in the Z axis direction where the lower end region 202 is provided may overlap each other at least partially. The high resistance region 204 may be in contact with a lower end of the trench portion arranged in the boundary portion 210. At least one of the drift region 18 or the accumulation region 16 may be arranged between the high resistance region 204 and the base region 14.

A width of the high resistance region 204 in the Z axis direction is defined as Wz. A maximum width of the high resistance region 204 in the Z axis direction may be used as the width Wz. A second length of the high resistance region 204 connecting the well region 11 and the lower end region 202 in the X axis direction is defined as Lx. A maximum length of the high resistance region 204 in the X axis direction may be used as the length Lx. The length Lx is preferably larger than the width Wz. The length Lx may be equal to or larger than twice, may be equal to or larger than 5 times, may be equal to or larger than 10 times, may be equal to or larger than 100 times the width Wz. The high resistance region 204 may be in contact with lower ends of two or more trench portions in the X axis direction. The high resistance region 204 may be in contact with lower ends of all trench portions provided in the boundary portion 210. The high resistance region 204 may cover two or more mesa portions in the X axis direction. Increasing the length Lx of the high resistance region 204 can increase electrical resistance between the well region 11 and the lower end region 202 and can increase potential difference between the well region 11 and the lower end region 202.

The high resistance region 204 may be in contact with a lower end of at least one gate trench portion 40. The high resistance region 204 may be in contact with lower ends of two or more gate trench portions 40. The high resistance region 204 may be in contact with lower ends of all gate trench portions 40 provided in the boundary portion 210.

FIG. 5B illustrates a view showing an example of net doping concentration distribution in a cross section a-a and a cross section b-b in FIG. 5A. A horizontal axis in FIG. 5B indicates a position in a Z axis direction with the upper surface 21 of the semiconductor substrate 10 as a reference position (0 μm). In FIG. 5B, the net doping concentration distribution in the cross section a-a in the transistor portion 70 is indicated by a dotted line, and the net doping concentration distribution in the cross section b-b in the boundary portion 210 is indicated by a solid line. The emitter region 12 and the base region 14 are provided in the neighborhood of the upper surface 21 of the cross section a-a of the transistor portion 70. The contact region 15 and the base region 14 are provided in the neighborhood of the upper surface 21 of the cross section b-b of the boundary portion 210. The net doping concentration distribution of the high resistance region 204 (solid line) has a lower concentration than the net doping concentration distribution of the lower end region 202 (dotted line). The net doping concentration distribution of the high resistance region 204 and the lower end region 202 may each have a peak or a maximum value. A full width at half maximum of the high resistance region 204 (FWHM1) may be smaller than a full width at half maximum of the lower end region 202 (FWHM2).

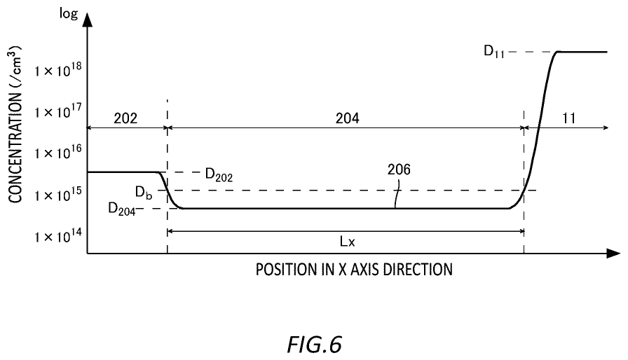

FIG. 6 illustrates a view showing an example of doping concentration distribution in a cross section c-c (X axis direction) in FIG. 5A. FIG. 6 shows concentration distribution in the high resistance region 204 and in the lower end region 202 and the well region 11 in the vicinity of the high resistance region 204. The cross section c-c may be a cross section at a peak position Zp in the net doping concentration distribution of each of the lower end region 202 and the high resistance region 204 shown in FIG. 5B.

A doping concentration of the lower end region 202 is defined as D₂₀₂. A maximum doping concentration in the lower end region 202 in the X axis direction may be used as the doping concentration D₂₀₂ of the lower end region 202. A doping concentration of the well region 11 is defined as D₁₁. A maximum doping concentration in the well region 11 may be used as the doping concentration D₁₁ of the well region 11. A doping concentration of the high resistance region 204 is defined as D₂₀₄. An average doping concentration or a minimum doping concentration in the high resistance region 204 in the X axis direction may be used as the doping concentration D₂₀₄ of the high resistance region 204.

The doping concentration D₂₀₄ is lower than the doping concentration D₂₀₂. The doping concentration D₂₀₄ may be equal to or lower than 10%, may be equal to or lower than 5%, or may be equal to or lower than 1% of the doping concentration D₂₀₂ of the lower end region 202. The doping concentration D₂₀₄ of the high resistance region 204 may be 1×10¹⁴/cm³ or more and 1×10¹⁷/cm³ or less. The doping concentration D₂₀₄ of the high resistance region 204 may be 1×10¹⁵/cm³ or more. The doping concentration D₂₀₄ of the high resistance region 204 may be 1×10¹⁶/cm³ or less.

Doping concentrations at both ends of the high resistance region 204 in the X axis direction are defined as Db. The doping concentration Db is a concentration between the maximum doping concentration in the lower end region 202 and the minimum doping concentration in the high resistance region 204. The doping concentration Db may be a middle concentration between the maximum doping concentration in the lower end region 202 and the minimum doping concentration in the high resistance region 204.

A position where the doping concentration first becomes Db in a direction from the lower end region 202 to the high resistance region 204 is defined as a boundary position between the lower end region 202 and the high resistance region 204. Similarly, a position where the doping concentration first becomes Db in a direction from the well region 11 to the high resistance region 204 is defined as a boundary position between the well region 11 and the high resistance region 204. The high resistance region 204 may have an overall doping concentration of Db or lower. The high resistance region 204 may include a flat portion 206 having flat doping concentration distribution in the X axis direction. The flat doping concentration distribution means that variation in the doping concentration is ±10% or less. The flat portion 206 may have a length in the X axis direction of 1 μm or more, 5 μm or more, or 10 μm or more. The length of the flat portion 206 may be equal to or larger than 50% or may be equal to or larger than 70% of the length Lx of the high resistance region 204.

In another example, the high resistance region 204 may include a portion having a doping concentration higher than Db. The high resistance region 204 may include a portion having a higher doping concentration than the lower end region 202. In this case, the doping concentration distribution in the high resistance region 204 in the X axis direction may have a peak. However, the average doping concentration of the high resistance region 204 is lower than an average doping concentration of the lower end region 202.

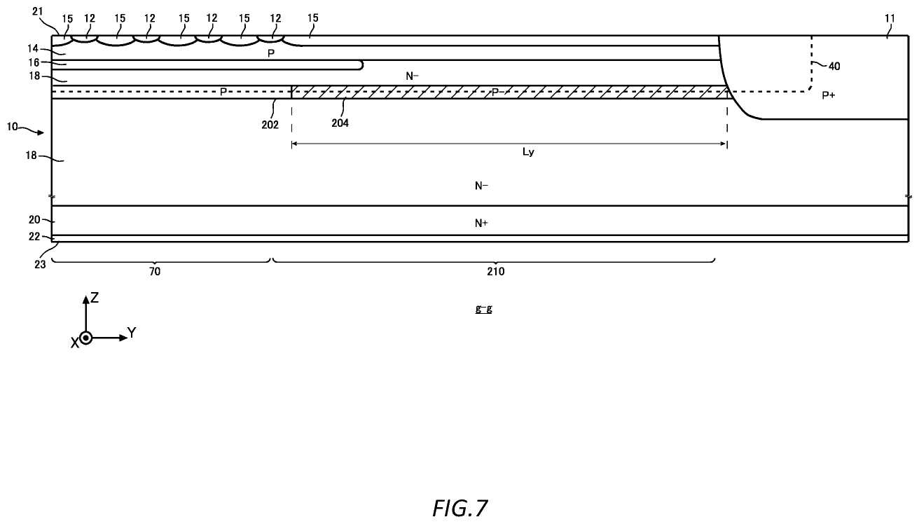

FIG. 7 illustrates a view showing an example of a cross section g-g in FIG. 4. The cross section g-g is a YZ plane passing through the lower end region 202, the high resistance region 204, and the well region 11. The cross section g-g passes through a mesa portion of the transistor portion 70. However, in FIG. 7, a position at which the gate trench portion 40 is projected on the cross section g-g is indicated by a dashed line. Note that FIG. 7 shows a structure of the semiconductor substrate 10 and omits components such as an electrode and a dielectric film arranged above and below the semiconductor substrate 10.

In the cross section as well, a region between the transistor portion 70 and the well region 11 is defined as a boundary portion 210. An end of the emitter region 12 arranged at an end in a Y axis direction among the emitter regions 12 is defined as an end portion of the transistor portion 70 in the Y axis direction. A range of the boundary portion 210 in the Y axis direction is defined to be from the emitter region 12 to the well region 11.

The emitter region 12 and the contact region 15 are alternately arranged along the Y axis direction in the upper surface 21 of the transistor portion 70. The contact region 15 is provided in the upper surface 21 of the boundary portion 210.

The accumulation region 16 of this example is provided to extend closer to the well region 11 than an end portion of the transistor portion 70. In another example, the accumulation region 16 may be terminated at the end portion of the transistor portion 70 or may be terminated inside the transistor portion 70.

The lower end region 202 of this example extends closer to the well region 11 than an end portion of the transistor portion 70. In another example, the lower end region 202 may be terminated at the end portion of the transistor portion 70 or may be terminated inside the transistor portion 70. The accumulation region 16 may extend closer to the well region 11 than the lower end region 202.

The high resistance region 204 is provided in at least part of the boundary portion 210 in the Y axis direction. The high resistance region 204 may be provided all over the boundary portion 210 in the Y axis direction. The high resistance region 204 may be in contact with the lower end region 202 and may be in contact with the well region 11. The high resistance region 204 of this example is in contact with both the lower end region 202 and the well region 11. The high resistance region 204 may overlap the accumulation region 16 in a top view. That is, an end portion of the accumulation region 16 may be inside the high resistance region 204 or inside the boundary portion 210 in the top view. In another example, the high resistance region 204 may not overlap the accumulation region 16 in the top view. That is, the end portion of the accumulation region 16 may be farther inward than (on a −Y axis direction side with respect to) the high resistance region 204 or the boundary portion 210 in the top view. The high resistance region 204 may be provided not to overlap the transistor portion 70 in the cross section. In another example, the high resistance region 204 may overlap the transistor portion 70 in the cross section.

A first length of the high resistance region 204 connecting the well region 11 and the lower end region 202 in the Y axis direction is defined as Ly. A maximum length of the high resistance region 204 in the Y axis direction may be used as the length Ly. The Y axis direction is a direction in which the trench portion has a longitudinal length, and the X axis direction is a direction in which the trench portion has a lateral length. A ratio between the length Ly and the length Lx (Ly/Lx) may be 0.9 or more and 1.1 or less. That is, the length Ly and the length Lx may be substantially equal. This can reduce variation in breakdown voltage in an XY plane.

In addition, the length Ly may be larger than the width Wz. The length Ly may be equal to or larger than twice, may be equal to or larger than 5 times, may be equal to or larger than 10 times, may be equal to or larger than 100 times the width Wz.

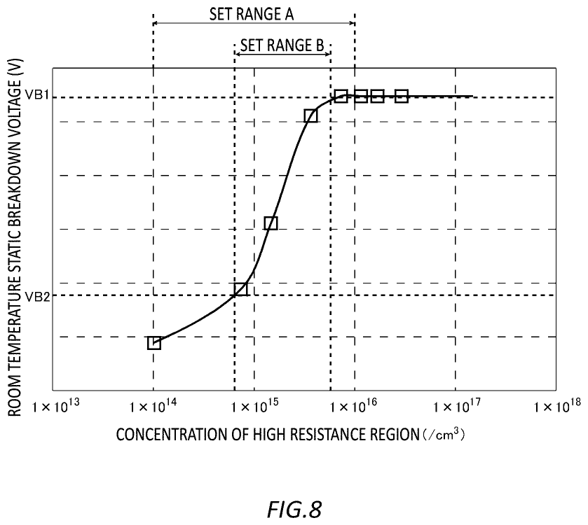

FIG. 8 shows a result obtained by measuring relationship between a doping concentration of the high resistance region 204 and breakdown voltage of a portion where the high resistance region 204 is formed. In FIG. 8, breakdown voltage VB1 indicates breakdown voltage of a portion where the lower end region 202 is formed, and breakdown voltage VB2 indicates breakdown voltage for a case where neither the lower end region 202 nor the high resistance region 204 is formed.

The doping concentration of the high resistance region 204 may be set such that the breakdown voltage of the portion where the high resistance region 204 is provided is higher than the breakdown voltage VB2 and lower than the breakdown voltage VB1. In this example, a lower limit of a set range of the doping concentration of the high resistance region 204 is 1×10¹⁴/cm³ or more and 1×10¹⁵/cm³ or less. In addition, an upper limit of the set range is 1×10¹⁵/cm³ or more and 1×10¹⁶/cm³ or less. FIG. 8 shows two set ranges A and B as examples of set ranges. As an example, the set range A is 1×10¹⁴/cm³ or more and 1×10¹⁶/cm³ or less. In another example, the set range B is 7×10¹⁴/cm³ or more and 6×10¹⁵/cm³ or less. In addition, a ratio α of a peak concentration of the doping concentration of the high resistance region 204 to a peak concentration of the doping concentration of the lower end region 202 may be 0.05 or more, may be 0.08 or more, may be 0.1 or more, or may be 0.3 or more. In addition, the ratio α may be 0.9 or less, may be 0.8 or less, may be 0.6 or less, or may be 0.5 or less.

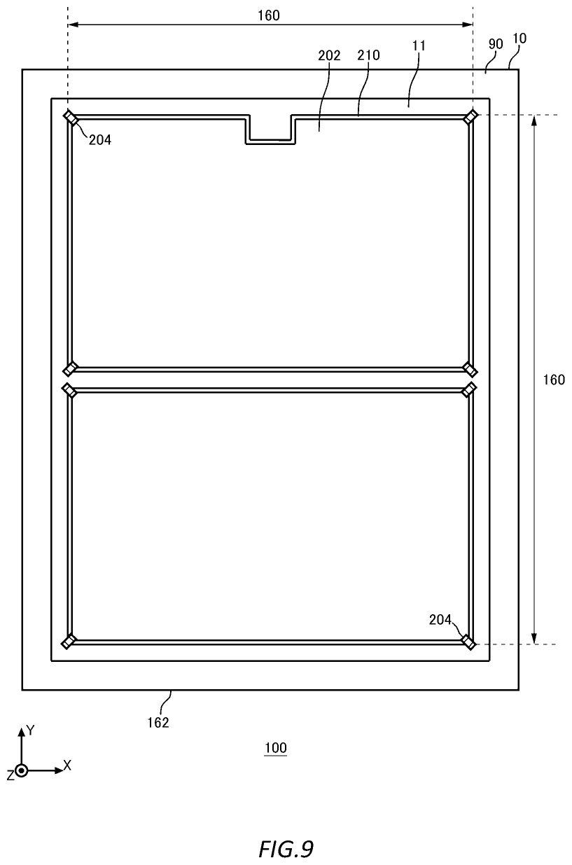

FIG. 9 illustrates a view showing another example of arrangement of the high resistance region 204 in a top view. The high resistance region 204 of this example is partially provided in a region between the lower end region 202 and the well region 11. That is, there is a portion where the high resistance region 204 is provided and a portion where the high resistance region 204 is not provided in the region (the boundary portion 210) between the lower end region 202 and the well region 11. The drift region 18 may be provided in stead of the high resistance region 204 in the region where the high resistance region 204 is not provided.

The high resistance region 204 of this example is arranged at a corner of the active portion 160 enclosed by the well region 11. The active portion 160 enclosed by the well region 11 in this example has a side parallel to a Y axis and a side parallel to an X axis. The high resistance region 204 may be provided at a position where the two sides intersect. As shown in FIG. 9, the high resistance regions 204 may be arranged at a plurality of corners. Since electric fields tend to concentrate at these corners, it is preferable to improve breakdown voltage by providing the high resistance regions 204.

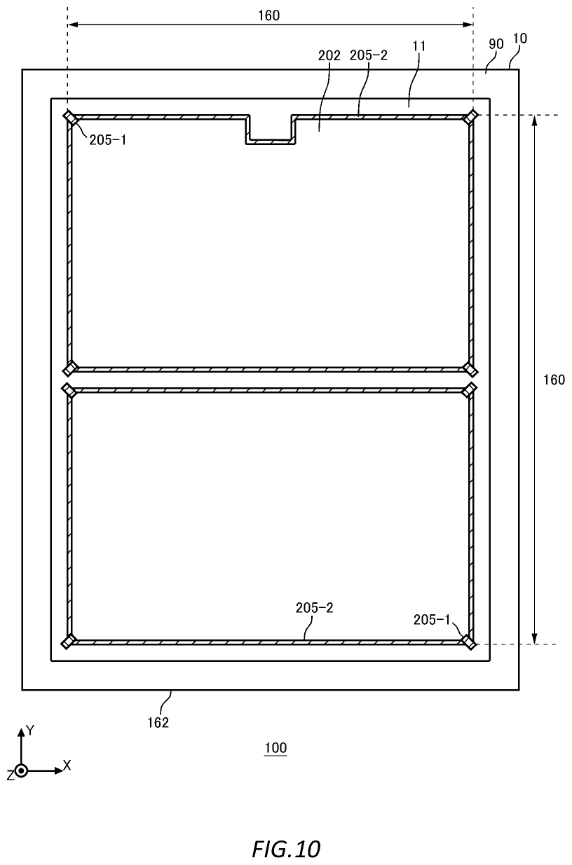

FIG. 10 illustrates a view showing another example of arrangement of the high resistance region 204 in a top view. The high resistance region 204 of this example has a first high resistance portion 205-1 and a second high resistance portion 205-2. The second high resistance portion 205-2 (linear portion) is a region having a lower doping concentration than the first high resistance portion 205-1 (corner). The first high resistance portion 205-1 is preferably arranged in a portion which requires higher breakdown voltage. The first high resistance portion 205-1 may be arranged at the corner like the high resistance region 204 described in FIG. 9. The second high resistance portion 205-2 is arranged in a region where the first high resistance portion 205-1 is not provided in a region between the lower end region 202 and the well region 11. This can suppress variation in breakdown voltage in an XY plane. Note that both the first high resistance portion 205-1 and the second high resistance portion 205-2 have lower doping concentrations than the lower end region 202.

In each of the embodiments described in FIG. 1 to FIG. 10, the high resistance region 204 may have a lower doping concentration than the base region 14. A maximum doping concentration in the high resistance region 204 may be equal to or lower than half, may be equal to or lower than 10%, or may be equal to or lower than 1% of a maximum doping concentration in the base region 14. A maximum doping concentration in the lower end region 202 may be lower than the maximum doping concentration in the base region 14 and higher than the maximum doping concentration in the high resistance region 204.

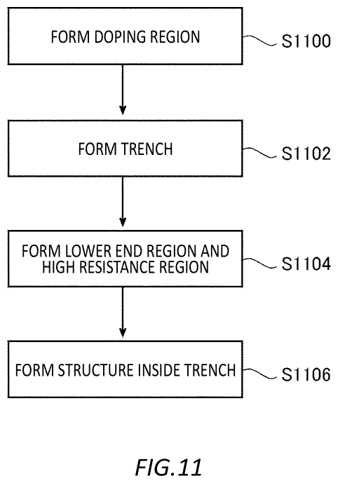

FIG. 11 illustrates a view showing part of a process of a method for manufacturing the semiconductor device 100. In the method for manufacturing the semiconductor device 100, each component described in FIG. 1 to FIG. 10 is formed. The process shown in FIG. 11 includes a first region forming step S1100, a trench forming step S1102, a second region forming step S1104, and a trench structure forming step S1106.

The first region forming step S1100 forms a doping region arranged on the upper surface 21 side of the semiconductor substrate 10. The doping region includes, for example, at least one of the well region 11, the emitter region 12, the base region 14, the contact region 15, or the accumulation region 16. Note that the drift region 18 may be a region remaining without the above described doping regions formed.

The trench forming step S1102 forms a trench in the upper surface 21 of the semiconductor substrate 10. The trench is a groove for forming each trench portion. Each trench is formed from the upper surface 21 to a depth reaching the drift region 18. The trench forming step S1102 does not form at least a conductive portion in the trench. A dielectric film in the trench may be formed or may not be formed.

The second region forming step S1104 forms the lower end region 202 and the high resistance region 204. The second region forming step S1104 may implant a dopant ion of a P type into the semiconductor substrate 10 via the trench. The second region forming step S1104 may implant the dopant ion of the P type from the upper surface 21 of the semiconductor substrate 10 while masking portions other than the trench. This allows the dopant ion of the P type to be easily implanted into a region in contact with a lower end of the trench. The first region forming step S1100 and the second region forming step S1104 heat-treat the semiconductor substrate 10 after implanting the dopant.

The trench structure forming step S1106 forms the conductive portion and the dielectric film inside each trench. The trench structure forming step S1106 may form the dielectric film by thermally oxidizing an inner wall of the trench. The trench structure forming step S1106 may form the conductive portion by filling a conductive material such as polysilicon into the trench where the dielectric film is formed.

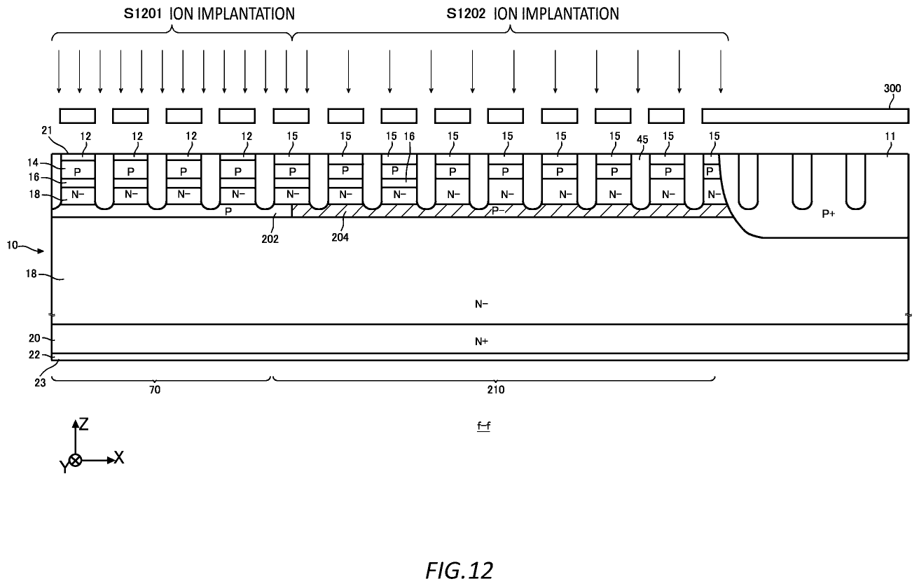

FIG. 12 illustrates a view describing an example of the second region forming step S1104. The second region forming step S1104 of this example has a first implantation step S1201 and a second implantation step S1202. Either the first implantation step S1201 or the second implantation step S1202 may be performed first.

The first implantation step S1201 implants a dopant ion of a P type having a predetermined concentration (km′) into a region where the lower end region 202 is to be formed. The second implantation step S1202 implants the dopant ion of the P type having a different concentration (km′) from that in the first implantation step S1201 into a region where the high resistance region 204 is to be formed. The concentration (dose amount) in the second implantation step S1202 is lower than the concentration in the first implantation step S1201. Note that both the first implantation step S1201 and the second implantation step S1202 may implant a dopant into the semiconductor substrate 10 via a trench 45. In this case, a mask 300 may mask a region other than the trench 45. Heat treatment diffuses the dopant implanted via the trench 45. This can form the lower end region 202 and the high resistance region 204 which are continuous in an XY plane.

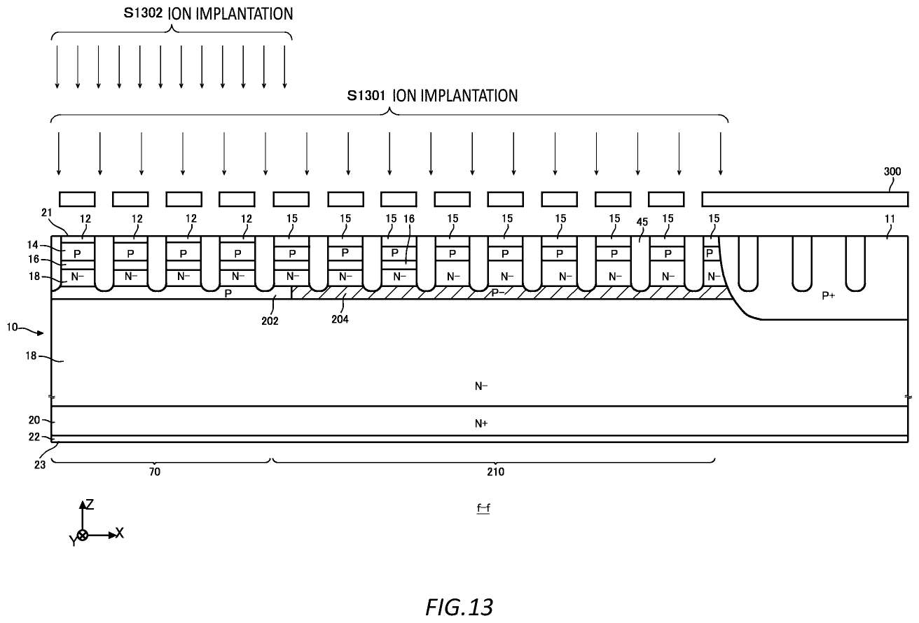

FIG. 13 illustrates a view describing another example of the second region forming step S1104. The second region forming step S1104 of this example has a first implantation step S1301 and a second implantation step S1302. Either the first implantation step S1301 or the second implantation step S1302 may be performed first.

The first implantation step S1301 implants a dopant ion of a P type having a predetermined concentration (km 2) into both a region where the high resistance region 204 is to be formed and a region where the lower end region 202 is to be formed. The second implantation step S1302 further implants a dopant ion of a P type having a predetermined concentration (km 2) into a region where the lower end region 202 is to be formed. The second implantation step S1302 does not implant the dopant ion into the region where the high resistance region 204 is to be formed. Note that both the first implantation step S1301 and the second implantation step S1302 may implant a dopant into the semiconductor substrate 10 via the trench 45. Heat treatment diffuses the dopant implanted via the trench 45. This can form the lower end region 202 and the high resistance region 204 which are continuous in an XY plane.

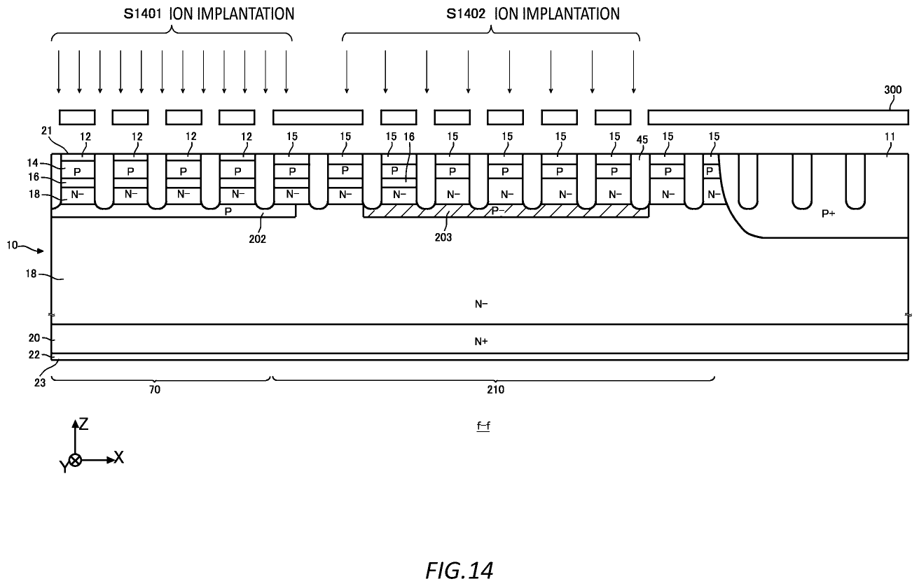

FIG. 14 illustrates a view describing another example of the second region forming step S1104. The second region forming step S1104 of this example has a first implantation step S1401 and a second implantation step S1402. Either the first implantation step S1401 or the second implantation step S1402 may be performed first or both may be performed at the same time.

The first implantation step S1401 implants a dopant ion of a P type having a predetermined concentration (km 2) into a region where the lower end region 202 is to be formed. The second implantation step S1402 implants a dopant ion of a P type having a predetermined concentration (km 2) into a region where the high resistance region 204 is to be formed. However, the second implantation step S1402 implant a dopant of a second conductivity type into a region 203 away from the region where the lower end region 202 is to be formed, in the region where the high resistance region 204 is to be formed. The region 203 may also be away from the well region 11. Distance between the region 203 and the lower end region 202 in an X axis direction may be larger than a width of one mesa portion of the boundary portion 210 in the X axis direction. Distance between the region 203 and the well region 11 in the X axis direction may also be larger than the width of the one mesa portion of the boundary portion 210 in the X axis direction.

The semiconductor substrate 10 is heat-treated after the second implantation step S1402, so that the implanted dopant is diffused toward the region where the lower end region 202 is to be formed. The heat treatment diffuses the dopant in a direction of the well region 11 as well. This forms the high resistance region 204 described in FIG. 1 to FIG. 10. The heat treatment is preferably performed at temperature and time which allow the dopant implanted into the region 203 to reach the lower end region 202 and the well region 11.

The concentration (km 2) for implantation in the second implantation step S1402 may be lower than, may be the same as, or may be higher than the concentration (/cm²) for implantation in the first implantation step S1401. Even if the concentration for the implantation in the second implantation step S1402 is equal to or higher than the concentration for the implantation in the first implantation step S1401, the dopant implanted in the second implantation step S1402 diffuses toward the lower end region 202 and the well region 11. Thus, an average doping concentration in the high resistance region 204 can be reduced.

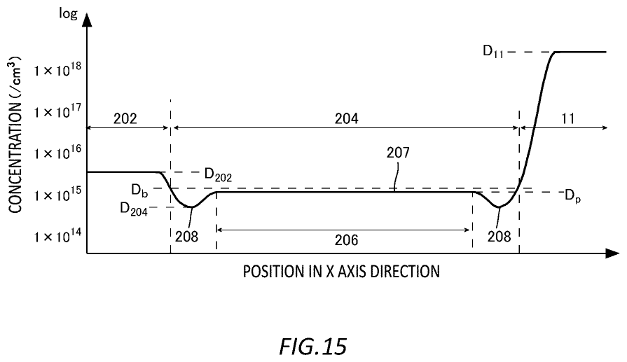

FIG. 15 illustrates a view showing another example of doping concentration distribution in an X axis direction. FIG. 15 shows concentration distribution in the high resistance region 204 and in the lower end region 202 and the well region 11 in the vicinity of the high resistance region 204. Doping concentrations of the lower end region 202 and the well region 11 are similar to the one in the example of FIG. 6.

The high resistance region 204 of this example is formed in the method described in FIG. 14. The high resistance region 204 of this example has a doping concentration peak 207 in a direction (for example, X axis direction) connecting the lower end region 202 and the well region 11. A local maximum of the peak 207 may be the flat portion 206.

The high resistance region 204 may have one or more valley portions 208 in the doping concentration distribution in the X axis direction. The valley portion 208 may be arranged between the peak 207 and the lower end region 202. The valley portion 208 may be arranged between the peak 207 and the well region 11. A doping concentration of the valley portion 208 may be defined as the doping concentration D₂₀₄ of the high resistance region 204. The doping concentration D₂₀₄ may be equal to or lower than 10%, may be equal to or lower than 5%, or may be equal to or lower than 1% of the doping concentration D₂₀₂ of the lower end region 202. The doping concentration D₂₀₄ may be higher than a doping concentration of the drift region 18.

A doping concentration of the peak 207 is defined as D p. The doping concentration D p of the peak 207 may be equal to or higher than 0.5 times and equal to or lower than 1.5 times the doping concentration D₂₀₂ of the lower end region 202. The doping concentration D p may be equal to or higher than 0.7 times or may be equal to or higher than 0.9 times the doping concentration D₂₀₂. In addition, the doping concentration D p may be equal to or lower than 1.3 times or may be equal to or lower than 1.1 times the doping concentration D₂₀₂. The doping concentration D p may be the same as the doping concentration D₂₀₂.

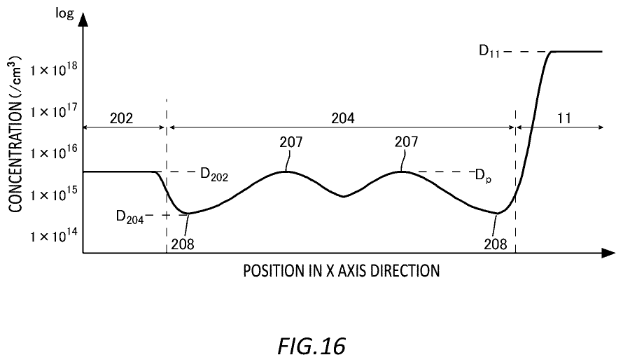

FIG. 16 illustrates a view showing another example of doping concentration distribution in an X axis direction. FIG. 16 shows concentration distribution in the high resistance region 204 and in the lower end region 202 and the well region 11 in the vicinity of the high resistance region 204. Doping concentrations of the lower end region 202 and the well region 11 are similar to the one in the example of FIG. 6.

The high resistance region 204 of this example has a plurality of doping concentration peaks 207. Doping concentrations D p of respective peaks 207 may be the same or may be different. For example, the doping concentration D p of the peak 207 may be higher as the well region 11 is closer. The plurality of peaks 207 can be formed by locally implanting dopants into a plurality of locations in a region where the high resistance region 204 is to be formed.

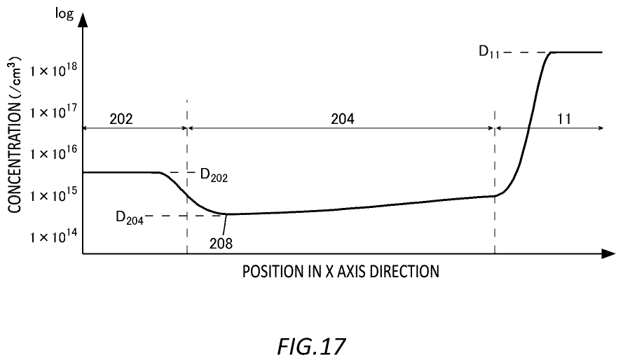

FIG. 17 illustrates a view showing another example of doping concentration distribution in an X axis direction. FIG. 17 shows concentration distribution in the high resistance region 204 and in the lower end region 202 and the well region 11 in the vicinity of the high resistance region 204. Doping concentrations of the lower end region 202 and the well region 11 are similar to the one in the example of FIG. 6. The high resistance region 204 of this example has the doping concentration valley portion 208. The valley portion 208 of this example is arranged closer to the lower end region 202 than a center of the high resistance region 204 in the X axis direction. In the doping concentration distribution, a slope from the valley portion 208 to the well region 11 may be more gradual than a slope from the valley portion 208 to the lower end region 202.

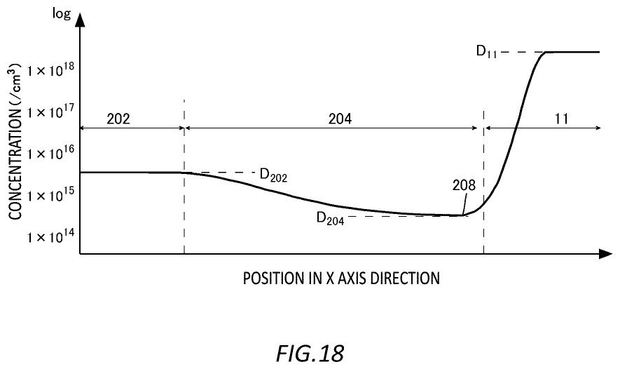

FIG. 18 illustrates a view showing another example of doping concentration distribution in an X axis direction. FIG. 18 shows concentration distribution in the high resistance region 204 and in the lower end region 202 and the well region 11 in the vicinity of the high resistance region 204. Doping concentrations of the lower end region 202 and the well region 11 are similar to the one in the example of FIG. 6. The high resistance region 204 of this example has the doping concentration valley portion 208. The valley portion 208 of this example is arranged closer to the well region 11 than a center of the high resistance region 204 in the X axis direction. In the doping concentration distribution, a slope from the valley portion 208 to the well region 11 may be steeper than a slope from the valley portion 208 to the lower end region 202.

As described in FIG. 6 and FIG. 15 to FIG. 18, potential distribution in the high resistance region 204 can be controlled by controlling doping concentration distribution in the high resistance region 204. Note that, the doping concentration distribution of the high resistance region 204 connecting the well region 11 and the lower end region 202 in the X axis direction has been described in FIG. 6 and FIG. 15 to FIG. 18, but the doping concentration distribution of the high resistance region 204 connecting the well region 11 and the lower end region 202 in a Y axis direction may be similar.

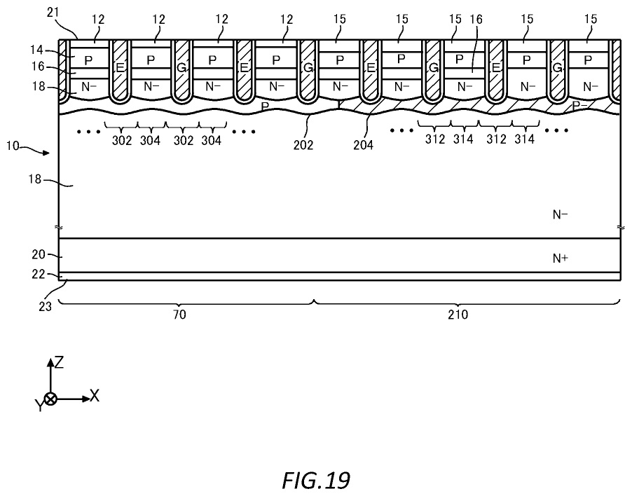

FIG. 19 illustrates a view showing another example of configuration of the lower end region 202 and the high resistance region 204. The lower end region 202 has a lower end portion 302 in contact with a lower end of a trench portion and a low concentration portion 304 having a lower doping concentration than the lower end portion 302. The high resistance region 204 also has a lower end portion 312 in contact with the lower end of the trench portion and a low concentration portion 314 having a lower doping concentration than the lower end portion 312. Each of the low concentration portion 304 and the low concentration portion 314 overlaps a center of a mesa portion in an X axis direction.

The lower end region 202 and the high resistance region 204 of this example are formed by implanting a dopant into the semiconductor substrate 10 via the trench 45 and thermally diffusing the dopant, as described in FIG. 12 to FIG. 14. Thus, the doping concentrations of the lower end portion 302 and the lower end portion 312 in contact with the trench portion are relatively high. Then, the doping concentrations of the low concentration portion 304 and the low concentration portion 314 away from the trench portion are relatively low.

In addition, a width of the low concentration portion 304 in a Z axis direction is smaller than a width of the lower end portion 302 in the Z axis direction. Similarly, a width of the low concentration portion 314 in the Z axis direction is smaller than a width of the lower end portion 312 in the Z axis direction.

Voltage (for example, −15 V) lower than voltage (for example, 0 V) of the emitter electrode 52 is applied to the gate trench portion 40. Thus, a hole tends to be attracted in the vicinity of a lower end of the gate trench portion 40. The hole attracted to the lower end of the gate trench portion 40 is easily extracted to the upper surface 21 side of the semiconductor substrate 10 by increasing the doping concentration of the lower end portion 312. This can shorten switching time of the semiconductor device 100. In addition, the lower end regions 202 extending in a horizontal direction (X axis direction) from adjacent trench portions in the transistor portion 70 are connected at a central portion of the mesa portion 60, so that decrease in breakdown voltage can be prevented. The same applies to a boundary between the boundary portion 210 and the boundary portion 210, and the transistor portion 70.

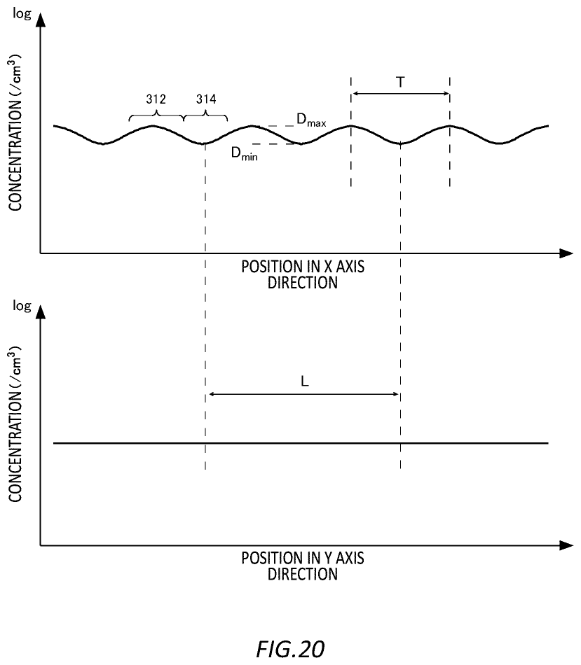

FIG. 20 illustrates a view showing an example of doping concentration distribution of the high resistance region 204. FIG. 20 shows the doping concentration distribution in an X axis direction of the high resistance region 204 connecting the well region 11 and the lower end region 202 in the X axis direction and the doping concentration distribution in a Y axis direction of the high resistance region 204 connecting the well region 11 and the lower end region 202 in the Y axis direction.

The high resistance region 204 of this example has the lower end portion 312 and the low concentration portion 314 alternately in the X axis direction. Thus, a high concentration portion and a low concentration portion alternately appear in the doping concentration distribution in the X axis direction.

In contrast, since a trench portion extends in the Y axis direction, the doping concentration distribution of the high resistance region 204 in the Y axis direction is substantially flat. That is, the doping concentration distribution of the high resistance region 204 in the Y axis direction is flatter than the doping concentration distribution of the high resistance region 204 in the X axis direction. A degree of flatness in the doping concentration distribution is indicated by difference between a maximum doping concentration D max and a minimum doping concentration Dₘᵢₙ in a unit length L in the X axis direction or the Y axis direction. The unit length L may be larger than an array period T of trench portions in the X axis direction (or peak-to-peak distance T of the doping concentration distribution of the high resistance region 204). According to this example, electric field distribution in the Y axis direction can be made flatter. Note that the high resistance region 204 has been described in FIG. 20, but the same applies to doping concentration distribution in the lower end region 202.

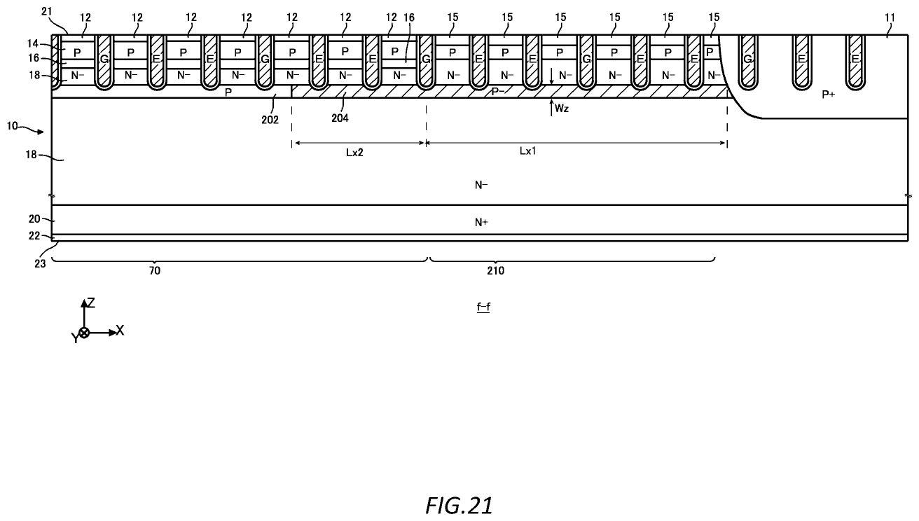

FIG. 21 illustrates a view showing another example of arrangement of the high resistance region 204 in an X axis direction. In this example, part of the emitter region 12 and part of the high resistance region 204 are arranged to overlap each other in a top view. That is, the high resistance region 204 of this example is provided to extend to an interior of the transistor portion 70. A length Lx1 in the X axis direction of the high resistance region 204 provided in the boundary portion 210 may be larger than a length Lx2 in the X axis direction of the high resistance region 204 provided in the transistor portion 70. The length Lx1 and the length Lx2 may be the same, or the length Lx2 may be larger than the length Lx1.

While the present invention has been described by way of the embodiments, the technical scope of the present invention is not limited to the scope described in the above-described embodiments. It is apparent to persons skilled in the art that various alterations or improvements can be made to the above-described embodiments. It is apparent from the description of the claims that embodiments added with such alterations or improvements can also be included in the technical scope of the present invention.

it should be noted that the operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described using phrases such as “first” or “next” in the claims, embodiments, or diagrams for convenience, it does not necessarily mean that the process must be performed in this order.

What is claimed is:

1. A semiconductor device comprising:
a semiconductor substrate which has an upper surface and a lower surface and includes a drift region of a first conductivity type;
a base region of a second conductivity type provided between the drift region and the upper surface of the semiconductor substrate;
a plurality of trench portions provided from the upper surface of the semiconductor substrate to below the base region;
a lower end region of the second conductivity type provided in contact with lower ends of two or more trench portions among the plurality of trench portions;
a well region of the second conductivity type which is arranged at a position different from the lower end region in a top view, is provided from the upper surface of the semiconductor substrate to below the base region, and has a higher doping concentration than the base region; and
a high resistance region of the second conductivity type which is arranged between the lower end region and the well region in the top view and has a lower doping concentration than the lower end region.

2. The semiconductor device according to claim 1, wherein
the high resistance region connects the lower end region and the well region.

3. The semiconductor device according to claim 1, wherein
a length of the high resistance region in the top view is larger than a width of the high resistance region in a depth direction of the semiconductor substrate.

4. The semiconductor device according to claim 1, wherein
the high resistance region is in contact with lower ends of two or more of the trench portions.

5. The semiconductor device according to claim 1, further comprising
an active portion enclosed by the well region in the top view, wherein
the high resistance region is arranged at a position in contact with the well region in the active portion.

6. The semiconductor device according to claim 5, wherein
the high resistance region encloses the active portion in the top view.

7. The semiconductor device according to claim 5, wherein the high resistance region includes:
a first high resistance portion arranged at a corner of the active portion in the top view; and
a second high resistance portion having a lower doping concentration than the first high resistance portion.

8. The semiconductor device according to claim 1, wherein
the high resistance region has a lower doping concentration than the base region.

9. The semiconductor device according to claim 1, wherein
a doping concentration of the high resistance region is equal to or lower than 10% of a doping concentration of the lower end region.

10. The semiconductor device according to claim 1, wherein
the high resistance region has a peak of a doping concentration in a direction connecting the lower end region and the well region.

11. The semiconductor device according to claim 10, wherein
a doping concentration at the peak in the high resistance region is equal to or higher than 0.5 times and equal to or lower than 1.5 times a doping concentration of the lower end region.

12. The semiconductor device according to claim 1, further comprising
an emitter region of the first conductivity type which is provided between the base region and the upper surface of the semiconductor substrate and has a higher doping concentration than the drift region, wherein
part of the emitter region and part of the high resistance region overlap each other in the top view.

13. The semiconductor device according to claim 1, further comprising
an emitter region of the first conductivity type which is provided between the base region and the upper surface of the semiconductor substrate and has a higher doping concentration than the drift region, wherein
the emitter region and the high resistance region are arranged away from each other in the top view.

14. The semiconductor device according to claim 1, wherein
the plurality of trench portions include one or more gate trench portions, and
the high resistance region is in contact with a lower end of at least one gate trench portion of the gate trench portions.

15. The semiconductor device according to claim 14, wherein the high resistance region includes:
a lower end portion in contact with the lower end of the gate trench portion; and
a low concentration portion having a lower doping concentration than the lower end portion.

16. The semiconductor device according to claim 1, further comprising
an accumulation region which is provided between the base region and the drift region and has a higher doping concentration than the drift region, wherein
part of the accumulation region and part of the high resistance region overlap each other in the top view.

17. The semiconductor device according to claim 1, wherein
the trench portion has a longitudinal length in a first direction and has a lateral length in a second direction in the top view, and
a ratio between a first length of the high resistance region connecting the lower end region and the well region in the first direction and a second length of the high resistance region connecting the lower end region and the well region in the second direction is 0.9 or more and 1.1 or less.

18. The semiconductor device according to claim 1, wherein
the trench portion has a longitudinal length in a first direction and has a lateral length in a second direction in the top view, and
a doping concentration distribution of the high resistance region in the first direction is flatter than the doping concentration distribution of the high resistance region in the second direction.

19. The semiconductor device according to claim 1, further comprising
an active portion enclosed by the well region in the top view, wherein
the lower end region is provided in a region occupying 90% or more of the active portion in the top view.

20. The semiconductor device according to claim 5, wherein
the high resistance region is arranged at a corner of the active portion in the top view.

21. The semiconductor device according to claim 1, wherein
the high resistance region is not provided in the upper surface of the semiconductor substrate.

22. The semiconductor device according to claim 1, wherein
a doping concentration of the lower end region is higher than a doping concentration of the base region.

23. The semiconductor device according to claim 1, wherein
the high resistance region spreads over the plurality of trench portions.

24. The semiconductor device according to claim 1, wherein
the semiconductor substrate includes a mesa portion which is a region sandwiched between a plurality of the trench portions,
the drift region is also provided in the mesa portion, and
part of the drift region provided in the mesa portion and part of the high resistance region overlap each other in the top view.

25. A method for manufacturing a semiconductor device, the method forming:
in a semiconductor substrate which has an upper surface and a lower surface and includes a drift region of a first conductivity type,
a base region of a second conductivity type provided between the drift region and the upper surface of the semiconductor substrate;
a plurality of trench portions provided from the upper surface of the semiconductor substrate to below the base region;
a lower end region of the second conductivity type provided in contact with lower ends of two or more trench portions among the plurality of trench portions;
a well region of the second conductivity type which is arranged at a position different from the lower end region in a top view, is provided from the upper surface of the semiconductor substrate to below the base region, and has a higher doping concentration than the base region; and
a high resistance region of the second conductivity type which is arranged between the lower end region and the well region in the top view and has a lower doping concentration than the lower end region.

26. The method for manufacturing a semiconductor device according to claim 25, wherein
a dopant of the second conductivity type is implanted into both a region where the high resistance region is to be formed and a region where the lower end region is to be formed, and
the dopant of the second conductivity type is further implanted into the region where the lower end region is to be formed.

27. The method for manufacturing a semiconductor device according to claim 25, wherein
dopants of the second conductivity type having different concentrations are respectively implanted into a region where the high resistance region is to be formed and a region where the lower end region is to be formed.

28. The method for manufacturing a semiconductor device according to claim 25, wherein
a dopant of the second conductivity type is implanted into a region away from a region where the lower end region is to be formed, in a region where the high resistance region is to be formed, and a heat treatment is performed, to diffuse the dopant toward the region where the lower end region is to be formed.

29. The method for manufacturing a semiconductor device according to claim 25, wherein
in the forming the high resistance region, a mask masks a region other than the plurality of trench portions, and a dopant is implanted into the semiconductor substrate via the plurality of trench portions.
